(19) United States
(12) Patent Application Publication
(10) Pub. No.: US 2025/0104745 A1
(43) Pub. Date: Mar. 27, 2025

(54) Current Control Systems And Methods For Communications Between Devices

(71) Applicant: Intel Corporation, Santa Clara, CA (US)

(72) Inventors: Kasper Wszolek, Gdansk (PL); Atul Maheshwari, Portland, OR (US); Ankireddy Nalamalpu, Portland, OR (US); Siang Poh Loh, Sungai Petani (MY)

(73) Assignee: Intel Corporation, Santa Clara, CA (US)

(21) Appl. No.: 18/372,696

(22) Filed: Sep. 25, 2023

(51) Int. Cl. G11C 7/10

(52) U.S. Cl. CPC G11C 7/1063; G11C 7/1057; G11C 7/1084

(57) ABSTRACT

An integrated circuit includes a communication controller circuit for exchanging communications with a device external to the integrated circuit through a signal line, a current circuit coupled to the signal line, and a current controller circuit for causing the current circuit to provide a constant current to the signal line while a signal is transmitted through the signal line based on a command generated by the communication controller circuit.

### TECHNICAL FIELD

The present disclosure relates to current control systems and methods for communications between devices.

### BACKGROUND ART

I3C (Improved Inter Integrated Circuit) is a specification that enables communications between integrated circuit (IC) devices. The I3C specification defines the electrical connections and the signaling protocol used in communications between IC devices. The I3C specification defines the electrical connections between the IC devices as including a shared serial data bus having two wires. One of the wires is used for a clock signal that defines sampling times, and the other wire is used as a data line for a data signal.

The I3C specification was designed to retain some backward compatibility with the I2C standard for computer systems. For example, the I3C specification allows designs where existing I2C devices can be connected to an I3C bus, but still have the I3C bus able to switch to a higher data rate for communication at higher speeds between I3C compliant devices. The I3C specification thereby combines the advantage of the simple, two wire I2C architecture with the higher communication speeds common to more complicated buses such as the Serial Peripheral Interface (SPI). The I3C specification was developed as a collaborative effort between electronics and computer related companies under the Mobile Industry Processor Interface (MIPI) Alliance.

### BRIEF DESCRIPTION OF DRAWINGS

FIG. 1 is a diagram that illustrates an example of an electronic system including two integrated circuit (IC) devices that exchange signals using a standard communication protocol.

FIG. 2 is a diagram that illustrates details of an example of the input/output (IO) circuit shown in FIG. 1.

FIG. 3 is a diagram that illustrates an example of a programmable logic IC that can implement techniques disclosed herein.

### DETAILED DESCRIPTION

The MIPI I3C specification is used on server platforms and in communications with field programmable gate arrays (FPGAs) that are used to fan out to multiple I3C interfaces on the server platforms. The MIPI I3C specification requires the use of a dynamically switched pull-up resistor. Some types of FPGAs have a built-in weak pull-up resistor, but the resistor can only be turned on and off during FPGA configuration. As a result, an I3C implementation of FPGA logic requires external pull-up logic outside the FPGA that is switched by additional input/output (IO) circuitry. The external pull-up logic increases cost and board area.

According to some examples disclosed herein, an integrated circuit includes a communication controller circuit, a current controller circuit, and an input/output (IO) circuit for communicating with an external device. The 10 circuit includes an input buffer, an output buffer, and a pull-up circuit. The pull-up circuit can include a transistor and a resistor. The communication controller circuit can transmit data to the external device through the output buffer and a signal line coupled to the external device. The communication controller circuit can receive data from the external device through the input buffer and the signal line coupled to the external device. The current controller circuit can dynamically turn on the pull-up circuit in response to a command from the communication controller circuit to provide a pull-up current through the resistor and the transistor to a signal transmitted or received by the input/output circuit during one or more operating modes. The current controller circuit can dynamically turn the pull-up circuit off to stop the flow of the pull-up current through the input/output circuit during other operating modes.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including programmable (configurable) integrated circuits, such as field programmable gate arrays (FPGAs). As discussed herein, an integrated circuit (IC) can include hard logic and/or soft logic. As used herein, “hard logic” generally refers to circuits in an integrated circuit device that are not programmable by an end user. The circuits in an integrated circuit device (e.g., in a programmable IC) that are programmable by the end user are referred to as “soft logic.”

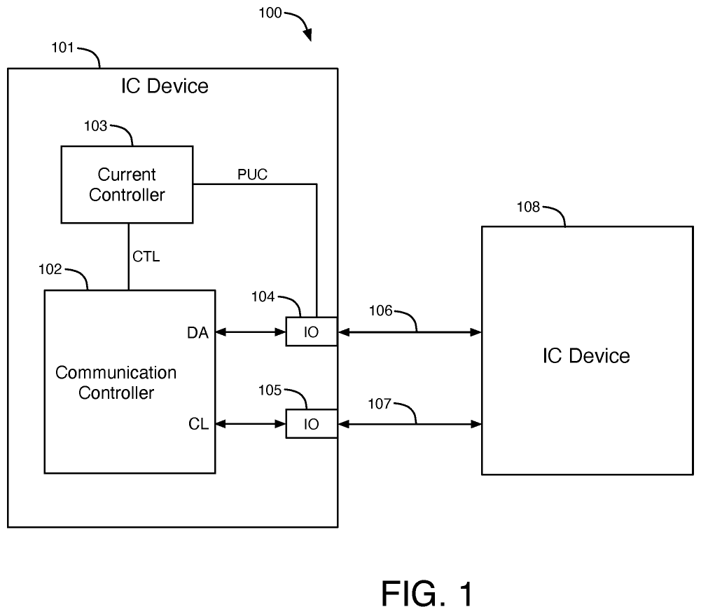

FIG. 1 is a diagram that illustrates an example of an electronic system 100 that includes two integrated circuit devices that exchange signals using a standard communication protocol. The electronic system 100 of FIG. 1 includes an integrated circuit (IC) device 101 and an IC device 108. IC devices 101 and 108 are coupled together through bidirectional signal lines (i.e., conductors or wires) 106-107. IC devices 101 and 108 can communicate through signal lines 106-107 according to any standard communication protocol or specification, such as I3C. IC devices 101 and 108 can be any types of integrated circuits. For example, one or both of IC devices 101 and 108 can be configurable/programmable logic ICs (e.g., FPGAs), microprocessor ICs, graphics processing unit (GPU) ICs, memory ICs, application specific integrated circuits (ASICs), etc. IC device 101 includes a communication controller circuit 102, a current controller circuit 103, and input/output (IO) circuits 104-105. The communication controller circuit 102 is coupled to the current controller circuit 102 and to the IO circuits 104-105.

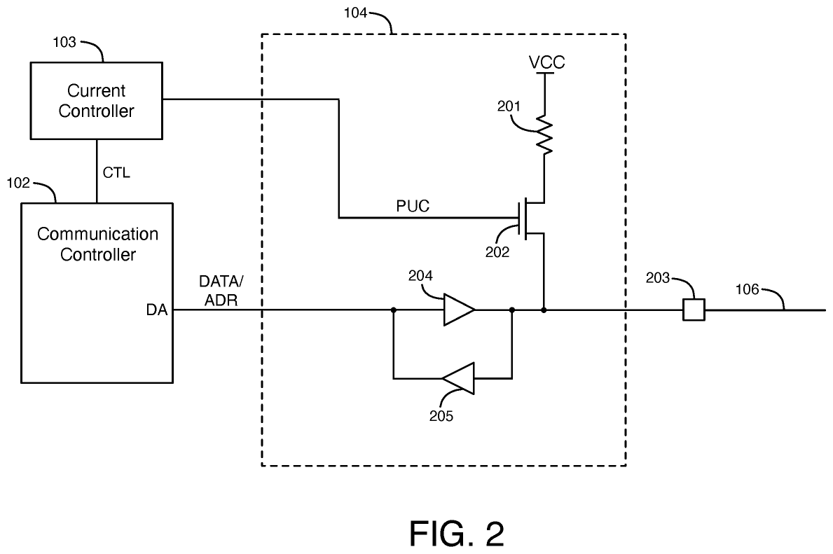

FIG. 2 is a diagram that illustrates details of an example of the input/output (IO) circuit 104 shown in FIG. 1. In the example of FIG. 2, the IO circuit 104 includes a resistor 201, an n-channel field-effect transistor (FET) 202, an external conductive pad 203 of IC 101, an output buffer circuit 204, and an input buffer circuit 205. Resistor 201 is coupled to a supply line that receives a supply voltage VCC. Transistor 202 is coupled between resistor 202 and pad 203. An input of output buffer circuit 204 is coupled to the DA port of communication controller circuit 102, and an output of output buffer circuit 204 is coupled to pad 203. An input of input buffer circuit 205 is coupled to pad 203, and an output of input buffer circuit 205 is coupled to the DA port of communication controller circuit 102.

Referring to FIGS. 1 and 2, the communication controller circuit 102 can, for example, generate data or addresses at its DA port and transmit the data (e.g., as signal DATA) or addresses (e.g., as signal ADR) serially from its DA port to the external IC device 108 through the signal line 106 using the output buffer circuit 204 in 10 circuit 104 during a transmit mode of operation. The communication controller circuit 102 can, for example, receive data (e.g., as signal DATA) or addresses (e.g., as signal ADR) serially at its DA port from the external IC device 108 through the signal line 106 using the input buffer circuit 205 in the IO circuit 104 during a receive mode of operation.

Referring to FIG. 1, the communication controller circuit 102 can, for example, generate a clock signal at its CL port and transmit the clock signal to the external IC device 108 through the IO circuit 105 and the signal line 107 coupled to the IC device 108 during the transmit mode of operation. The communication controller circuit 102 can receive a clock signal at its CL port from the external IC device 108 through the signal line 107 and the IO circuit 105 during the receive mode of operation. The clock signals transmitted between IC devices 101 and 108 can be used, for example, to sample the data transmitted through signal line 106.

The MIPI I3C specification requires the use of a dynamically switched pull-up resistor that is coupled to the signal line used to transmit data and address signals. According to the MIPI I3C specification, the switched pull-up resistor is turned on to provide backward compatibility for communications with external devices according to the older I2C standard. In addition, according to the MIPI I3C specification, the switched pull-up resistor is turned on during transmission of address signals for I3C data communications with an external device.

According to a specific example disclosed herein, the resistor 201 and the transistor 202 shown in FIG. 2 function as the switched pull-up resistor that is required by the MIPI I3C specification to provide pull-up current in some modes of operation, such as data transmission according to the I2C standard or address signal transmission for I3C data communications. In this example, the communication controller circuit 102 is an I3C controller circuit. The I3C controller circuit in this example can be implemented by soft logic or hard logic in a programmable logic IC device 101. In other exemplary implementations, the resistor 201 and the transistor 202 can be used to provide pull-up current to a signal line for other communications standards or protocols.

By providing resistor 201 and transistor 202 in the IC device 101, electronic system 100 does not require additional board level components that are external to IC device 101 to implement the switched pull-up resistor for I3C. Thus, resistor 201 and transistor 202 reduce circuit board usage. In addition, IC device 101 does not need to use an additional 10 circuit or external pad or pin to control the switched pull-up resistor, because resistor 201 and transistor 202 are implemented within IC device 101. Thus, resistor 201 and transistor 202 reduce the usage of IO resources in IC device 101.

The conductive state of transistor 202 is controlled by a pull-up control signal PUC that is generated by the current controller circuit 103. The current controller circuit 103 adjusts the voltage of signal PUC to turn transistor 202 on to enable a mode of operation that requires a constant pull-up current through resistor 201 and transistor 202 to signal line 106 for transmission of a signal through signal line 106. As examples that are not intended to be limiting, a mode of operation that requires pull-up current through resistor 201 and transistor 202 to signal line 106 can be a mode of operation that enables backward compatibility for data transmission according to the I2C standard through signal line 106 with IC device 108 or a mode of operation for transmission of address signals through signal line 106 with external IC device 108.

The current controller circuit 103 generates the pull-up control signal PUC at least in part based on a command generated by the communication controller circuit 102 in one or more control signals CTL. Before or during a mode of operation that requires pull-up current through resistor 201 and transistor 202 to signal line 106, the communication controller circuit 102 adjusts the one or more control signals CTL to a first value or a first set of values that are indicative of the communication controller circuit 102 entering or being in a mode of operation that requires pull-up current through resistor 201 and transistor 202 to signal line 106 while a signal is transmitted through signal line 106. In response to receiving the first value or the first set of values of signal(s) CTL, the current controller circuit 103 adjusts the pull-up control signal PUC to a voltage that causes transistor 202 to turn on. For example, current controller circuit 103 can increase the voltage of signal PUC to supply voltage VCC to cause transistor 202 to be in saturation.

A constant current then flows from the supply line at supply voltage VCC through resistor 201 and transistor 202 to signal line 106 to enable transmission of a signal through signal line 106 in a mode of operation that requires pull-up current through a pull-up resistor/transistor (e.g., resistor 201 and transistor 202). Communication controller circuit 102 then transmits a signal through output buffer circuit 204 and signal line 106 and/or receives a signal through signal line 106 and input buffer circuit 205 in this mode of operation (e.g., data transmission for I2C or address transmission), while the constant current flows from VCC through resistor 201, transistor 202, and one of output buffer circuit 204 or input buffer circuit 205. The constant current flows from VCC through resistor 201, transistor 202, and one of output buffer circuit 204 or input buffer circuit 205 during both logic high states and logic low states in the signal transmitted through the signal line 106. The constant pull-up current provided through resistor 201 and transistor 202 can be, for example, a weak pull-up current as required by the I3C specification.

Before or during a mode of operation that does not require pull-up current through resistor 201 and transistor 202 to signal line 106, the communication controller circuit 102 adjusts the one or more control signals CTL to a second value or a second set of values that are indicative of the communication controller circuit 102 entering or being in a mode of operation that requires zero pull-up current through resistor 201 and transistor 202 to signal line 106 for signal transmission through signal line 106. In response to receiving the second value or the second set of values of signal(s) CTL, the current controller circuit 103 adjusts the pull-up control signal PUC to a voltage that causes transistor 202 to turn off. For example, current controller circuit 103 can decrease the voltage of signal PUC to a ground voltage to cause transistor 202 to be off. When transistor 202 is off, transistor 202 blocks current flow from the supply line at supply voltage VCC through resistor 201 to signal line 106. Transistor 202 being off enables signal transmission through signal line 106 in a mode of operation that requires zero pull-up current through resistor 201 and transistor 202. Communication controller circuit 102 then transmits signals through output buffer circuit 204 and signal line 106 and/or receives signals through signal line 106 and input buffer circuit 205 in this mode of operation (e.g., data transmission for I3C).

According to an exemplary implementation that is not intended to be limiting, the current controller circuit 103 is a JTAG (Joint Test Action Group) controller circuit that dynamically controls the current through transistor 202 and resistor 201 using control signal PUC, as described above, in response to one or more JTAG commands generated by the communication controller circuit 102 in signal(s) CTL. Thus, in this implementation, the JTAG controller circuit turns transistor 202 on to provide weak pull-up current through resistor 201 to signal line 106 in modes of operation that require the weak pull-up current. The JTAG controller circuit can be implemented in circuit 103 using soft logic circuits and/or hard logic circuits in a programmable logic IC 101.

According to another exemplary implementation that is not intended to be limiting, the IC device 101 is a programmable logic IC, and the current controller circuit 103 is a secure device manager (SDM) circuit that controls security functions for the programmable logic IC. In this implementation, the SDM circuit runs firmware and/or includes an application programming interface (API) that dynamically controls the current through transistor 202 and resistor 201 using control signal PUC, as described above, in response to commands generated by the communication controller circuit 102 in signal(s) CTL that are generated to control the firmware or API. Thus, in this implementation, the SDM circuit turns transistor 202 on to provide weak pull-up current through resistor 201 to signal line 106 in modes of operation that require the weak pull-up current. The SDM circuit can be implemented in circuit 103 using soft logic circuits and/or hard logic circuits in IC device 101.

The exemplary implementations disclosed herein that use JTAG or SDM can provide access to control an internal pull-up resistor state, such as resistor 201. According to other alternative exemplary implementations that are not intended to be limiting, other programming interfaces with similar capabilities to JTAG can be used, such as internal or external SPI, I2C, Universal Asynchronous Receiver-Transmitter (UART), Universal Serial bus (USB), Peripheral Component Interconnection express (PCIe), or other interfaces that allow for FPGA device programming.

Thus, the current controller circuit 103 can be, as examples, an internal JTAG controller or an SDM that dynamically controls the on-chip pull-up transistor 202 to provide current through resistor 201 to signal line 106 during some modes of operation. The logic circuitry in IC device 101 that implements the communication controller circuit 102 can use internal JTAG commands (e.g., in signals CTL) that are provided to the JTAG controller, SDM, or direct SDM API in circuit 103 to control the conductive state of transistor 202 dynamically as required by any communications standard, such as the I3C specification.

In some implementations, IC device 101 can use on-chip resources and capabilities to turn a statically configurable pull-up transistor and resistor that are coupled in series into a dynamic pull-up circuit, as disclosed herein with respect to FIG. 2. As a result, in these implementations, changes do not need to be made to the hardware in IC device 101 to enable the configuration disclosed herein with respect to FIGS. 1-2. Instead, the techniques disclosed herein with respect to FIGS. 1-2 can be implemented by changes in the firmware run by current controller circuit 103 and/or communication controller circuit 102 and/or changes in the configuration of current controller circuit 103 and/or communication controller circuit 102. If current controller circuit 103 and/or communication controller circuit 102 are implemented by soft logic, the configuration of current controller circuit 103 and/or communication controller circuit 102 can be set or changed by configuration data loaded into memory in IC device 101.

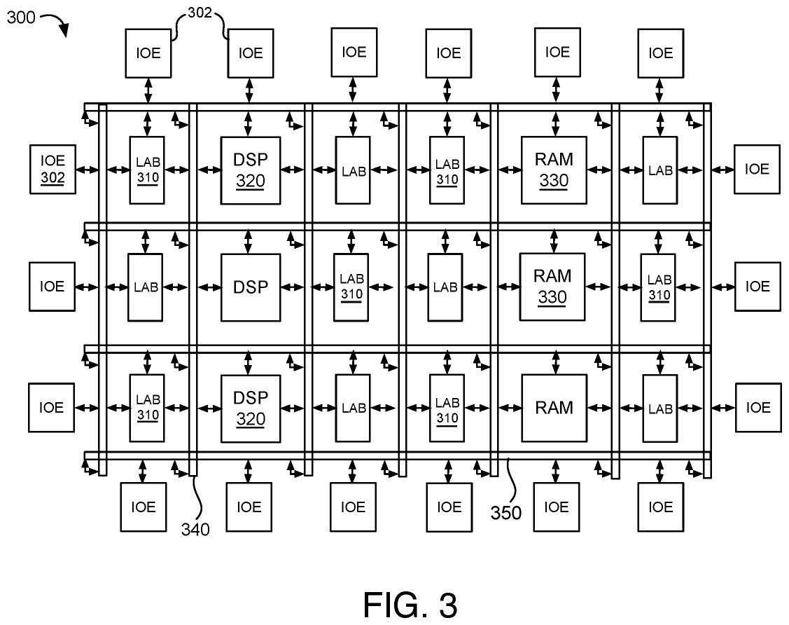

FIG. 3 illustrates an example of a programmable logic IC 300 that can implement techniques disclosed herein. Any one or more of the IC devices 101 or 108 can include the architecture of programmable logic IC 300. As shown in FIG. 3, the programmable logic IC 300 includes a two-dimensional array of configurable functional circuit blocks, including configurable logic array blocks (LABs) 310 and other functional circuit blocks, such as random access memory (RAM) blocks 330 and digital signal processing (DSP) blocks 320. Functional blocks such as LABs 310 can include smaller programmable logic circuits (e.g., logic elements, logic blocks, or adaptive logic modules) that receive input signals and perform custom functions on the input signals to produce output signals.

In addition, programmable logic IC 300 can have input/output elements (IOEs) 302 for driving signals off of programmable logic IC 300 and for receiving signals from other devices. IOEs 302 may include parallel input/output circuitry, serial data transceiver circuitry, differential receiver and transmitter circuitry, or other circuitry used to connect one integrated circuit to another integrated circuit. As shown, IOEs 302 may be located around the periphery of the chip. If desired, the programmable logic IC 300 may have IOEs 302 arranged in different ways. For example, IOEs 302 may form one or more columns, rows, or islands of input/output elements that may be located anywhere on the programmable IC 300.

The programmable logic IC 300 can also include programmable interconnect circuitry in the form of vertical routing channels 340 (i.e., interconnects formed along a vertical axis of programmable logic IC 300) and horizontal routing channels 350 (i.e., interconnects formed along a horizontal axis of programmable logic IC 300), each routing channel including at least one track to route at least one wire.

Note that other routing topologies, besides the topology of the interconnect circuitry depicted in FIG. 3, may be used. For example, the routing topology may include wires that travel diagonally or that travel horizontally and vertically along different parts of their extent as well as wires that are perpendicular to the device plane in the case of three dimensional integrated circuits. The driver of a wire may be located at a different point than one end of a wire.

Furthermore, it should be understood that embodiments disclosed herein with respect to FIGS. 1-2 may be implemented in any integrated circuit or electronic system. If desired, the functional blocks of such an integrated circuit may be arranged in more levels or layers in which multiple functional blocks are interconnected to form still larger blocks. Other device arrangements may use functional blocks that are not arranged in rows and columns.

Programmable logic IC 300 may contain programmable memory elements. Memory elements may be loaded with configuration data using IOEs 302. Once loaded, the memory elements each provide a corresponding static control signal that controls the operation of an associated configurable functional block (e.g., LABs 310, DSP blocks 320, RAM blocks 330, or IOEs 302). The configuration data can set the functions of the configurable functional circuit blocks (soft logic) in IC 300.

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The programmable memory elements may be organized in a configuration memory array consisting of rows and columns. A data register that spans across all columns and an address register that spans across all rows may receive configuration data. The configuration data may be shifted onto the data register. When the appropriate address register is asserted, the data register writes the configuration data to the configuration memory bits of the row that was designated by the address register.

In certain embodiments, programmable logic IC 300 may include configuration memory that is organized in sectors, whereby a sector may include the configuration RAM bits that specify the functions and/or interconnections of the subcomponents and wires in or crossing that sector. Each sector may include separate data and address registers.

The programmable IC of FIG. 3 is merely one example of an IC that can include embodiments disclosed herein. The embodiments disclosed herein may be incorporated into any suitable integrated circuit or system. For example, the embodiments disclosed herein may be incorporated into numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein may be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is an integrated circuit comprising a communication controller circuit for exchanging communications with a device external to the integrated circuit through a signal line; a current circuit coupled to the signal line; and a current controller circuit for causing the current circuit to provide a constant current to the signal line while a signal is transmitted through the signal line based on a command generated by the communication controller circuit, wherein the current controller circuit comprises one of a secure device manager circuit or a Joint Test Action Group controller circuit.

In Example 2, the integrated circuit of Example 1 may optionally include, wherein the current circuit comprises a transistor coupled to the signal line.

In Example 3, the integrated circuit of any one of Examples 1-2 may optionally include, wherein the current circuit comprises a resistor.

In Example 4, the integrated circuit of any one of Examples 1-3 may optionally include, wherein the current circuit is a pull-up current circuit that provides the constant current to the signal line when the current circuit is on.

In Example 5, the integrated circuit of any one of Examples 1-4 may optionally include, wherein the current controller circuit causes the current circuit to provide the constant current to the signal line during logic high states and logic low states in the signal transmitted through the signal line.

In Example 6, the integrated circuit of any one of Examples 1-5 may optionally include, wherein the communication controller circuit is configurable to generate the command to cause the current controller circuit to turn on the current circuit to provide the constant current to the signal line during logic state variations in the signal transmitted through the signal line.

In Example 7, the integrated circuit of any one of Examples 1-6 further comprises an output buffer circuit, wherein the communication controller circuit transmits the signal to the device through the output buffer circuit and the signal line.

In Example 8, the integrated circuit of any one of Examples 1-7 further comprises an input buffer circuit, wherein the communication controller circuit receives the signal from the device through the signal line and the input buffer circuit.

In Example 9, the integrated circuit of any one of Examples 1-8 may optionally include, wherein the communication controller circuit exchanges the signal with the device through the signal line according to an I3C specification.

Example 10 is a method for controlling communications with a device external to an integrated circuit, the method comprising: exchanging a first signal with the device through a conductor using a communication controller circuit in the integrated circuit; generating a control signal using the communication controller circuit based on a first mode of operation used during transmission of the first signal; and generating a constant current between a transistor in the integrated circuit and the conductor during multiple logic states of the first signal using a current controller circuit in the integrated circuit, wherein the current controller circuit implements a secure device manager or a Joint Test Action Group controller that is responsive to the control signal.

In Example 11, the method of Example 10 may optionally include, wherein generating the control signal using the communication controller circuit further comprises generating the control signal based on the first mode of operation enabling backward compatibility with a communication standard.

In Example 12, the method of any one of Examples 10-11 may optionally include, wherein generating the control signal using the communication controller circuit further comprises generating the control signal based on the first mode of operation enabling transmission of addresses.

In Example 13, the method of any one of Examples 10-12 may optionally include, wherein generating the constant current between the transistor and the conductor further comprises turning the transistor on to provide the constant current through the transistor to the conductor during the first mode of operation.

In Example 14, the method of any one of Examples 10-13 may optionally include, wherein generating the constant current between the transistor and the conductor further comprises turning the transistor on to provide the constant current through a resistor and the transistor to the conductor during the first mode of operation.

In Example 15, the method of any one of Examples 10-14 further comprises turning the transistor off to block the constant current to the conductor in response to the control signal during a second mode of operation.

Example 16 is an integrated circuit comprising a transmission controller circuit for exchanging a signal with an external device through a conductor; an input/output circuit coupled to the conductor; and a logic controller circuit for causing the input/output circuit to provide a constant current between the input/output circuit and the conductor during logic state variations of the signal transmitted through the conductor in response to a command generated by the transmission controller circuit, wherein the logic controller circuit implements one of a secure device manager or a Joint Test Action Group controller.

In Example 17, the integrated circuit of Example 16 may optionally include, wherein the logic controller circuit causes the input/output circuit to provide the constant current to the conductor during logic high states in the signal and during logic low states in the signal.

In Example 18, the integrated circuit of any one of Examples 16-17 may optionally include, wherein the input/output circuit comprises a transistor coupled to an external signal pad of the integrated circuit, and wherein the logic controller circuit controls a conductive state of the transistor.

In Example 19, the integrated circuit of Example 18 may optionally include, wherein the input/output circuit further comprises a resistor coupled between a supply line and the transistor.

In Example 20, the integrated circuit of any one of Examples 16-19 may optionally include, wherein the transmission controller circuit generates the command to cause the logic controller circuit to turn on a transistor in the input/output circuit to provide the constant current to the conductor during transmission of the signal through the conductor.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

1. An integrated circuit comprising:
a communication controller circuit for exchanging communications with a device external to the integrated circuit through a signal line;
a current circuit coupled to the signal line; and
a current controller circuit for causing the current circuit to provide a constant current to the signal line while a signal is transmitted through the signal line based on a command generated by the communication controller circuit, wherein the current controller circuit comprises one of a secure device manager circuit or a Joint Test Action Group controller circuit.

2. The integrated circuit of claim 1, wherein the current circuit comprises a transistor coupled to the signal line.

3. The integrated circuit of claim 1, wherein the current circuit comprises a resistor.

4. The integrated circuit of claim 1, wherein the current circuit is a pull-up current circuit that provides the constant current to the signal line when the current circuit is on.

5. The integrated circuit of claim 1, wherein the current controller circuit causes the current circuit to provide the constant current to the signal line during logic high states and logic low states in the signal transmitted through the signal line.

6. The integrated circuit of claim 1, wherein the communication controller circuit is configurable to generate the command to cause the current controller circuit to turn on the current circuit to provide the constant current to the signal line during logic state variations in the signal transmitted through the signal line.

7. The integrated circuit of claim 1 further comprising:
an output buffer circuit, wherein the communication controller circuit transmits the signal to the device through the output buffer circuit and the signal line.

8. The integrated circuit of claim 1 further comprising:
an input buffer circuit, wherein the communication controller circuit receives the signal from the device through the signal line and the input buffer circuit.

9. The integrated circuit of claim 1, wherein the communication controller circuit exchanges the signal with the device through the signal line according to an I3C specification.

10. A method for controlling communications with a device external to an integrated circuit, the method comprising:
exchanging a first signal with the device through a conductor using a communication controller circuit in the integrated circuit;
generating a control signal using the communication controller circuit based on a first mode of operation used during transmission of the first signal; and
generating a constant current between a transistor in the integrated circuit and the conductor during multiple logic states of the first signal using a current controller circuit in the integrated circuit, wherein the current controller circuit implements a secure device manager or a Joint Test Action Group controller that is responsive to the control signal.

11. The method of claim 10, wherein generating the control signal using the communication controller circuit further comprises generating the control signal based on the first mode of operation enabling backward compatibility with a communication standard.

12. The method of claim 10, wherein generating the control signal using the communication controller circuit further comprises generating the control signal based on the first mode of operation enabling transmission of addresses.

13. The method of claim 10, wherein generating the constant current between the transistor and the conductor further comprises turning the transistor on to provide the constant current through the transistor to the conductor during the first mode of operation.

14. The method of claim 10, wherein generating the constant current between the transistor and the conductor further comprises turning the transistor on to provide the constant current through a resistor and the transistor to the conductor during the first mode of operation.

15. The method of claim 10 further comprising;
turning the transistor off to block the constant current to the conductor in response to the control signal during a second mode of operation.

16. An integrated circuit comprising:
a transmission controller circuit for exchanging a signal with an external device through a conductor;
an input/output circuit coupled to the conductor; and
a logic controller circuit for causing the input/output circuit to provide a constant current between the input/output circuit and the conductor during logic state variations of the signal transmitted through the conductor in response to a command generated by the transmission controller circuit, wherein the logic controller circuit implements one of a secure device manager or a Joint Test Action Group controller.

17. The integrated circuit of claim 16, wherein the logic controller circuit causes the input/output circuit to provide the constant current to the conductor during logic high states in the signal and during logic low states in the signal.

18. The integrated circuit of claim 16, wherein the input/output circuit comprises a transistor coupled to an external signal pad of the integrated circuit, and wherein the logic controller circuit controls a conductive state of the transistor.

19. The integrated circuit of claim 18, wherein the input/output circuit further comprises a resistor coupled between a supply line and the transistor.

20. The integrated circuit of claim 16, wherein the transmission controller circuit generates the command to cause the logic controller circuit to turn on a transistor in the input/output circuit to provide the constant current to the conductor during transmission of the signal through the conductor.
